(19) United States
(12) Patent Application Publication
(10) Pub. No.: US 2025/0374486 A1
(43) Pub. Date: Dec. 4, 2025

(54) HEAT SINK, HEAT SINK MANUFACTURING METHOD, AND COMPUTER

(71) Applicant: SUZHOU METABRAIN INTELLIGENT TECHNOLOGY CO., LTD., Suzhou, Jiangsu (CN)

(72) Inventors: Guang CHEN, Suzhou, Jiangsu (CN); Xingfang JIANG, Suzhou, Jiangsu (CN); Wenfang LI, Suzhou, Jiangsu (CN); Jingli SUN, Suzhou, Jiangsu (CN)

(73) Assignee: SUZHOU METABRAIN INTELLIGENT TECHNOLOGY CO., LTD., Suzhou, Jiangsu (CN)

(21) Appl. No.: 18/876,112

(22) PCT Filed: Mar. 17, 2023
(86) PCT No.: PCT/CN2023/082292

§ 371 Date: Dec. 17, 2024

(30) Foreign Application Priority Data
Oct. 21, 2022 (CN) 202211290992.7

(51) Int. Cl. H05K 7/20; F28F 21/08

(52) U.S. Cl. CPC H05K 7/20336; F28F 21/08; H05K 7/20409; F28F 2255/00

(57) ABSTRACT

Embodiments of the present disclosure relate to the field of computers, and provide a heat sink, a heat sink manufacturing method, and a computer. The heat sink includes a heat radiation structure body and a first cooling structure. The heat radiation structure body is provided with a slotted structure. The slotted structure extends in a temperature diffusion direction. An opening of the slotted structure is formed in one end of the heat radiation structure body away from a heat source. The first cooling structure is laid on an inner wall of the slotted structure. The first cooling structure is provided with cooling channels first cooling channels for adsorbing a liquid coolant. Through the above arrangement of the present disclosure, the problems of low heat radiation efficiency and poor heat radiation effect of the heat sink are solved, and the heat radiation efficiency is improved.

### CROSS-REFERENCE TO RELATED APPLICATION

The present application is a National Stage Application of PCT International Application No.: PCT/CN2023/082292 filed on Mar. 17, 2023, which claims priority to Chinese Patent Application 202211290992.7, filed in the China National Intellectual Property Administration on October 21, 2022, the disclosure of which is incorporated herein by reference in its entirety.

### TECHNICAL FIELD

The present disclosure relates to the field of computers, and in particular, to a heat sink, a heat sink manufacturing method, and a computer.

### BACKGROUND

At present, the integration of computer components is getting higher and higher, and the power consumption of products is also getting higher and higher, which leads to more and more serious heat radiation problems of computer components. At present, heat sinks made of Al and Cu materials are mostly used for heat radiation of Central Processing Units (CPUs) in the field of computers. This type of heat sink has a relatively large thermal resistance, which leads to a relatively large overall temperature difference of the heat sink and may not maximize the heat radiation effect of the heat sink. Therefore, the current heat sink may not meet the requirement for ever-increasing power consumption of the components.

### SUMMARY

Embodiments of the present disclosure provide a heat sink, a heat sink manufacturing method, and a computer, so as to at least solve the problems of low heat radiation efficiency and poor heat radiation effect of the heat sink in the related art.

In an embodiment of the present disclosure, a heat sink is provided, which includes a heat radiation structure body and a first cooling structure. The heat radiation structure body is configured to arrange on one side of a heat source. The heat radiation structure is provided with a slotted structure. The slotted structure extends in a direction away from the heat source. An opening of the slotted structure is formed in one end of the heat radiation structure body away from the heat source. The first cooling structure is laid on an inner wall of the slotted structure. The first cooling structure is provided with first cooling channels for adsorbing a liquid coolant.

n an embodiment, the first cooling structure is a capillary structure, and pores in the capillary structure form the first cooling channels.

In an embodiment, a cross-section of the slotted structure is circular or rectangular, and the first cooling structure is arranged on a side wall and a bottom wall of the slotted structure.

In an embodiment, the heat radiation structure body is made from a vapor chamber.

In an embodiment, a ratio of a thickness of the bottom wall of the slotted structure to a thickness of the vapor chamber is 0.05 to 0.1.

In an embodiment, the thickness of the bottom wall of the slotted structure is 2 mm to 3 mm, and the thickness of the vapor chamber is 30 mm to 35 mm.

In an embodiment, the heat radiation structure body is of a radial structure, and the slotted structure is arranged at the center of the heat radiation structure body.

In an embodiment, the first cooling structure is made of Al powder or Cu powder, and the Al powder or the Cu powder is 200 mesh to 800 mesh.

In an embodiment, two heat radiation structure bodies are arranged in a mirror image manner, and the openings in the two heat radiation structure bodies are arranged opposite to each other, so that the slotted structures on the two heat radiation structure bodies jointly enclose a sealed space.

In an embodiment, the first cooling structure is arranged in the heat radiation structure body at one end close to the heat source, and the heat sink further includes a second cooling structure. The second cooling structure is arranged in the heat radiation structure body at one end away from the heat source. The second cooling structure further includes a plurality of second cooling channels. The liquid coolant is pre-stored in the plurality of second cooling channels. The second cooling structure is only laid on the side wall of the slotted structure.

In an embodiment, the heat sink further includes a sealing plate arranged at the opening of the slotted structure to cooperate with the slotted structure to form a sealed space.

In an embodiment, the opening of the slotted structure is provided with a counter bore, the depth of the counter bore is less than or equal to a thickness of the sealing plate, and the sealing plate completely falls into the counter bore.

In an embodiment, the sealing plate is provided with a groove on one side of the sealed space.

In an embodiment, the groove is of a groove structure with a deep middle and a shallow edge.

In another embodiment of the present disclosure, a heat sink manufacturing method is provided for manufacturing the above heat sink, and the heat sink manufacturing method includes: machining a slotted structure on an end surface of one end of a heat radiation structure body away from a heat source; and laying a first cooling structure on an inner wall of the slotted structure, causing the first cooling structure to include first cooling channels, and pre-storing a liquid coolant in the first cooling channels.

In an embodiment, the first cooling structure is formed by sintering Cu powder or Al powder on the inner wall of the slotted structure.

In an embodiment, two heat radiation structure bodies are placed together in a mirror image manner with one end away from the heat source as the center and are welded and fixed, so that the slotted structures on the two heat radiation structure bodies form a sealed space.

In an embodiment, a sealing plate covers an opening of the slotted structure and is welded and sealed, so that a sealed space is formed between the slotted structure and the sealing plate.

In an embodiment, after the first cooling structure is laid, the liquid coolant is injected into the slotted structure to cause the liquid coolant to flow into the first cooling channels. After the liquid coolant is injected, the sealed space is evacuated at a predetermined time interval.

In another embodiment of the present disclosure, a computer is provided, which includes a CPU and a heat sink. The heat sink is arranged on one side of the CPU, and the heat sink is the above heat sink, or the heat sink is manufactured by the above heat sink manufacturing method.

The heat sink of the present disclosure mainly uses a physical form to dissipate heat and cool down the heat source, and when in use, the heat sink is arranged on one side of the heat source. By arranging the slotted structure at one end of the heat radiation structure body, the slotted structure forms an inner cavity in the entire heat radiation structure body, thereby reducing the weight of the heat sink and reducing the thermal resistance of the heat radiation structure body. The first cooling structure is arranged in the slotted structure, and the first cooling channels on the first cooling structure may pre-store the liquid coolant to volatilize when heated, and quickly transfer heat to one end of the heat radiation structure body away from the heat source, thereby ensuring that the temperature of the heat radiation structure body is as consistent as possible, and then improving the overall heat radiation efficiency of the heat radiation structure body.

### BRIEF DESCRIPTION OF THE DRAWINGS

In order to more clearly illustrate the embodiments of the present disclosure, the drawings used in the embodiments will be briefly described below. It is apparent that the drawings described below are only some embodiments of the present disclosure. Other drawings may further be obtained by those of ordinary skill in the art according to these drawings without creative efforts.

FIG. 1 is a cross-sectional view of a heat sink according to some embodiments of the present disclosure.

FIG. 2 is a top view of a heat sink according to some embodiments of the present disclosure.

FIG. 3 is a schematic diagram of a first cooling structure according to some embodiments of the present disclosure.

### DETAILED DESCRIPTION OF THE EMBODIMENTS

Embodiments of the present disclosure are described below with reference to the drawings and in conjunction with the embodiments in detail.

It is to be noted that the terms “first”, “second” and the like in the description, claims and the above-mentioned drawings of the present disclosure are used for distinguishing similar objects rather than describing a specific sequence or a precedence order.

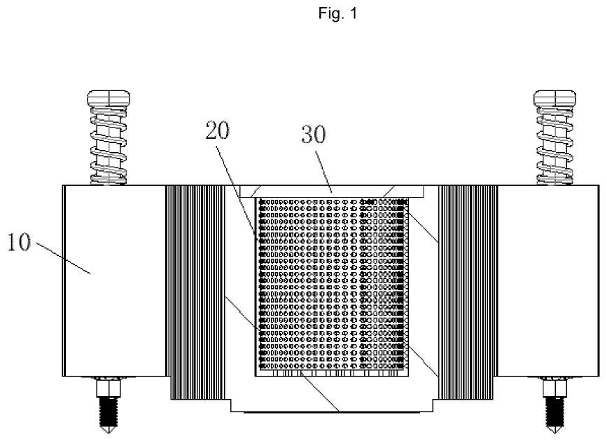

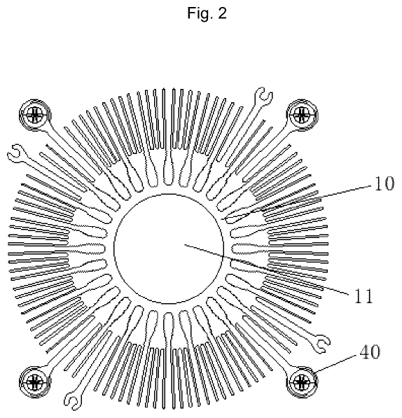

The embodiments of the present disclosure provide a heat sink, which may be arranged in a mobile terminal, a computer terminal or a similar computing device to dissipate heat of a heat source such as a CPU. As shown in FIG. 1 and FIG. 2, the heat sink includes a heat radiation structure body 10 and a first cooling structure 20. The heat radiation structure body 10 is arranged on one side of the heat source. The heat radiation structure 10 is provided with a slotted structure 11. The slotted structure 11 refers to a slot or hole with only one opening at one end, and may also be referred to as a blind hole. The slotted structure 11 extends in a direction away from the heat source. After the relative positions of the heat radiation structure body and the heat source are determined, the direction away from the heat source is also determined, that is, a direction from the heat source toward the heat radiation structure body. At this time, if one end of the slotted structure 11 is heated, heat may be directly transferred to the other end of the slotted structure 11 through the volatilization of a gas medium or a liquid coolant in the slotted structure 11, so as to be quickly transferred to one end away from the heat source, so that one end away from the heat source quickly heats up and dissipates heat quickly, thereby improving the heat radiation efficiency of the heat sink. After the slotted structure is machined, an inner cavity is formed in the heat radiation structure body, thereby reducing the thermal resistance of the heat radiation structure body. The opening of the slotted structure 11 is formed in one end of the heat radiation structure body 10 away from the heat source. The first cooling structure 20 is laid on and completely covers an inner wall of the slotted structure 11. The first cooling structure 20 is provided with first cooling channels, the liquid coolant is pre-stored in the first cooling channels, and the first cooling channels may be closed spaces or cavities with openings at one end.

The heat radiation structure body 10 of the present disclosure is made of a Cu or Al material, and is manufactured by processes such as extrusion or die-casting.

Taking the computer as an example, the heat source is the CPU, and the heat radiation structure body 10 is of a cylindrical structure, and is generally laid down when in use, that is, two end surfaces are on one side, and the CPU is on one side of the heat radiation structure body 10, so that one end of the heat radiation structure body 10 is close to the CPU, while the other end thereof is located on the back.

In order to ensure efficient and safe heat radiation, the slotted structure 11 uses the cylindrical structure, and one end of the opening of the cylindrical structure is arranged toward one end away from the heat source. The cylindrical structure is convenient to lay the first cooling structure 20. The first cooling structure 20 in the embodiment of the present disclosure is arranged on a side wall and a bottom wall of the slotted structure 11. Since the bottom of the slotted structure 11 is closest to the heat source, the first cooling structure 20 is laid on the bottom wall to prevent dry burning of the bottom wall of the slotted structure 11 on the heat sink, and the liquid coolant in the first cooling structure 20 laid on the bottom wall may volatilize more quickly after absorbing heat, and the heat radiation effect is better. A structural center of a conventional heat sink is a solid. When one end close to the CPU is heated, heat is transferred through the material of the conventional heat sink, and the heat transfer speed is slow, resulting in a relatively large temperature difference between two opposite ends of the conventional heat sink. One end away from the heat source has slow heat radiation efficiency due to a low temperature, so that the heat of one end close to the heat source is dissipated slowly. In order to solve this problem, the heat radiation principle of the above heat sink of the present disclosure when in use is as follows.

One end of the heat radiation structure body of the heat sink close to the heat source is heated first. An extension direction of the slotted structure of the present disclosure is an extension direction of an axis line of the above cylindrical structure. After the bottom wall of the slotted structure is heated first, the liquid coolant in the first cooling structure pre-stored on the bottom wall is heated and volatilized, thereby quickly bringing the heat to the other end of the heat radiation structure body, and accelerating the heat transfer efficiency. Secondly, the liquid coolant in the first cooling structure on the side wall of the slotted structure continues to volatilize and dissipate heat, thereby increasing the heat radiation area.

In another embodiment, the heat radiation structure body may also use a polygonal column structure.

In another embodiment, the slotted structure 11 may also be arranged as a structure such as a stepped hole, a dovetail slot or a trapezoidal hole.

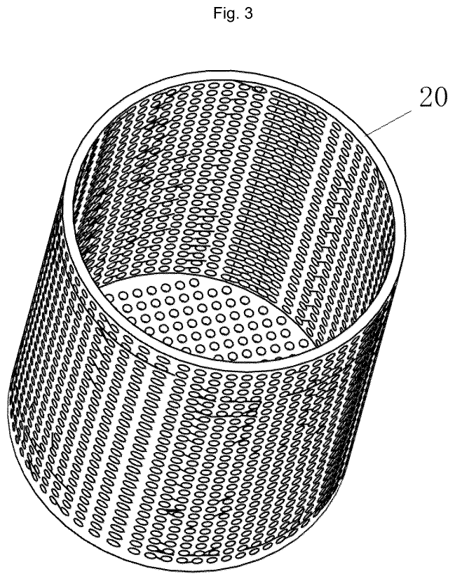

As shown in FIG. 3, the first cooling structure 20 in the present disclosure is in the form of a capillary structure, which is a cylindrical structure with one end open and the other end closed. The closed end is installed corresponding to the bottom wall. The capillary structure has good adsorption force, and pores in the capillary structure form the first cooling channels to adsorb the liquid coolant. In this embodiment, the heat radiation structure body 10 is made from a vapor chamber with a certain thickness. A distance between the bottom of the slotted structure 11 and the bottom of the vapor chamber is the thickness of the bottom wall of the slotted structure 11. A ratio of the thickness of the bottom wall to the thickness of the vapor chamber is generally 0.05 to 0.1. Preferably, the thickness of the bottom wall is 2 mm to 3 mm, and the thickness of the vapor chamber is 30 mm to 35 mm. If the thickness is too small, the entire heat radiation area is small. If the thickness is too thick, not only is the volume occupied, but also rapid heat radiation is not facilitated. The diameter of the slotted structure 11 is 30 mm to 40 mm, that is, the heat radiation structure body 10 of the present disclosure is not a sheet, but a Three-Dimensional (3D) vapor chamber with a certain thickness, which increases the heat radiation area. At the same time, the slotted structure 11 of the above size may ensure that the entire heat radiation structure body 10 achieves a rapid heat radiation effect.

The heat sink of the present disclosure is made from a 3D vapor chamber with gravity resistance, which may not only ensure temperature uniformity, but also increase the heat radiation capacity of the heat sink. The heat sink may be installed in a plurality of directions without considering gravity. Specifically, the heat sink may be placed horizontally or vertically, and a plurality of heat sinks may also be placed around the heat source at intervals. A cavity of the 3D vapor chamber is an inner cavity of the heat sink, which may reduce the weight of the heat sink and eliminate the thermal resistance between the 3D vapor chamber and the heat sink, thereby increasing the heat radiation capacity.

In order to improve the heat radiation effect as much as possible, the heat radiation structure body 10 is arranged as a radial sunflower structure, the overall outline is cylindrical, the heat radiation is uniform, the slotted structure 11 is arranged at the center of the heat radiation structure body 10, and a center line of the heat radiation structure body 10 coincides with a center line of the slotted structure 11.

In an embodiment, the first cooling structure 20 is also made of Al powder or Cu powder, and the Al powder or Cu powder is 200 mesh to 800 mesh. Preferably, the Al powder or Cu powder is 300 mesh, 400 mesh, 500 mesh, 600 mesh or 700 mesh, and the first cooling structure 20 has a better heat radiation effect under the pore size and density at this mesh size.

In an embodiment, the first cooling structure 20 and the heat radiation structure body 10 are both made of Al, or Cu. Of course, the first cooling structure may also be made of porous materials such as carbon fiber.

In order to cope with heat sources of different temperatures and sizes, two heat radiation structure bodies 10 are arranged in the heat sink of the present disclosure. When the volume and temperature of the heat source are relatively small, in order to reduce the occupied space, only one heat radiation structure body 10 is needed to dissipate heat of the heat source. However, when the volume and temperature of the heat source are relatively high, the two heat radiation structure bodies 10 in the embodiment of the present disclosure are arranged in a mirror image manner, and the openings in the two heat radiation structure bodies 10 are arranged opposite to each other, that is, sides with the openings are close to each other, so that the slotted structures 11 on the two heat radiation structure bodies 10 jointly enclose a sealed space, thereby increasing the volume and area of the entire heat sink. At the same time, the space of the slotted structure 11 in the middle of the heat sink is also enlarged, which may well adapt to the heat radiation of the heat sink with increased volume. Through the above arrangement, the heat sink of the present disclosure may match CPUs of different models, is convenient to disassemble and install, and has stronger adaptability.

In order to match the relatively large heat sink mentioned above, the first cooling structure 20 in the present disclosure is arranged in the heat radiation structure body 10 at one end close to the heat source, and the heat sink further includes a second cooling structure. The second cooling structure is provided with a plurality of second cooling channels, and the liquid coolant is pre-stored in the plurality of second cooling channels. Specifically, the second cooling structure also uses a capillary mechanism, and the second cooling structure is arranged in the heat radiation structure body 10 at one end away from the heat source. The second cooling structure is only laid on the side wall of the slotted structure 11, so that the side wall and the bottom wall are both provided with the capillary structures to absorb the liquid coolant in the sealed space formed by the two slotted structures 11, while the bottom wall of one end away from the heat source is retained without the capillary structure. At this time, the liquid coolant volatilized in the capillary structure condenses on the bottom wall without the capillary structure, thereby improving the heat radiation speed and effect. The liquid coolant in this embodiment may be pure water.

The first cooling channels and the plurality of second cooling channels are collectively called the cooling channels for brevity hereinafter.

When only one heat radiation structure body 10 is provided, in order to further improve the heat radiation effect of the heat radiation structure body, the heat sink of the present disclosure further includes a sealing plate 30. The sealing plate 30 is arranged at the opening to cooperate with the slotted structure 11 to form a sealed space, and the sealing plate 30 is sealed at the opening by brazing. The sealing plate 30 is provided with an injection hole for injecting liquid into the sealed space. After the injection is completed, part of the liquid coolant is sucked away through the injection hole, and the sealed space is evacuated, thereby improving the heat transfer efficiency in the sealed space.

In order to facilitate the installation of the sealing plate, the opening of the slotted structure is provided with a counter bore with a circular shape. The depth of the counter bore is consistent with the thickness of the sealing plate, or the thickness of the sealing plate is less than the depth of the counter bore, so that the sealing plate may completely fall into the counter bore when installed at the opening of the slotted structure.

When the sealing plate is added, the heat radiation principle of the entire heat sink is as follows.

One end of the heat radiation structure body of the heat sink close to the heat source is heated first. The extension direction of the slotted structure of the present disclosure is the extension direction of the axis line of the above cylindrical structure. After the bottom wall of the slotted structure is heated first, the liquid coolant in the first cooling structure pre-stored on the bottom wall is heated and volatilized, thereby quickly bringing the heat to the other end of the heat radiation structure body. At this time, since the sealing plate is located at one end away from the heat source, the temperature of the sealing plate is much lower than that of the bottom wall, and the volatilized liquid coolant releases heat and condenses after encountering the sealing plate with relatively low temperature, thereby quickly increasing the temperature of the sealing plate. The condensed liquid coolant flows again into the cooling channels of the capillary structures at the side wall, and then flows back to the cooling channels of the bottom wall to prevent overheating and dry burning of the bottom wall. The liquid coolant accelerates the heat transfer efficiency.

In order to further increase the reflux speed of the liquid coolant, the sealing plate 30 is provided with a groove on one side of the sealed space to facilitate the condensed liquid to flow back to the first cooling structure 20. The groove is a circular groove, and the diameter of the groove is the same as that of the slotted structure 11.

In an embodiment, the groove is arranged as a groove structure with a deep middle and a shallow edge, thereby achieving a certain guiding effect on the liquid coolant, and allowing the liquid coolant to flow back along an inner wall of the groove to the cooling channels at the side wall of the slotted structure.

The heat radiation structure body is further provided with a plurality of connection holes 40. The plurality of connection holes 40 are arranged around the heat radiation structure body at intervals, and two heat radiation structure bodies are connected through the connection holes 40 and screws.

The heat radiation structure body is further provided with a plurality of threaded holes. A screw passes through each of the plurality of threaded holes to fix the heat radiation structure body to a fan or computer housing. The plurality of connection holes 40 and the plurality of threaded holes may be multipurpose, and may be connected to another heat radiation structure and may also be configured to fix the heat sink to the fan or computer housing.

The embodiments of the present disclosure further provide a heat sink manufacturing method for manufacturing the above heat sink, and the heat sink manufacturing method includes the following operations.

First, Al or Cu is integrally die-casted to form a heat radiation structure body 10 of the present disclosure. As shown in FIG. 2, the heat radiation structure body 10 is of a sunflower-shaped structure, and the outer contour is a cylindrical structure, so that the heat radiation structure body 10 has two opposite end surfaces.

Further, a slotted structure 11 is milled on any one of the two opposite end surfaces of the heat radiation structure body 10, and when the heat sink is installed, the slotted structure 11 is ensured to be located at one end away from a heat source.

After the slotted structure 11 is machined, a first cooling structure 20 is laid on an inner wall of the slotted structure 11.

There are many arrangement manners of the first cooling structure 20. One embodiment is as follows: the first cooling structure 20 is formed by sintering Cu powder or Al powder on the inner wall of the slotted structure 11. In another embodiment, other forms may also be used, such as directly installing the first cooling structure 20 into the slotted structure 11 after manufacturing, but the effect is not as good as direct sintering due to the fact that the sintered first cooling structure 20 is more tightly connected to the slotted structure 11, and the heat transfer effect and the effect of storing the liquid coolant are better.

In an embodiment, Al powder or Cu powder is sintered at a temperature of 500° C. to 900° C. for 1 hour to 2 hours through a positioning structure such as a ceramic rod, so as to be sintered and fixed on an inner surface of the slotted structure to form the first cooling structure, and the first cooling structure has good water absorption.

For a high-power CPU or a high-temperature heat source, in the present disclosure, two heat radiation structure bodies 10 may be placed together and welded in a mirror image manner with one end away from the heat source as a center plane, that is, the two heat radiation structure bodies 10 are aligned, so that the slotted structures 11 on the two heat radiation structure bodies 10 form a sealed space, thereby increasing the heat radiation area of the heat sink structure, and the slotted structure 11 is adaptively enlarged, thereby ensuring the heat radiation effect of the enlarged heat sink, which has stronger adaptability and is convenient to install and disassemble.

The sealing plate 30 covers an opening of the slotted structure 11 and is welded and sealed, so that a sealed space is formed between the slotted structure 11 and the sealing plate 30.

For the above two implementations, when the implementation that two heat radiation structure bodies 10 are butted to form the sealed space is selected, the manufacturing method is as follows: after laying the first cooling structure 20 on one heat radiation structure body 10, the second cooling structure is continued to be laid on the other heat radiation structure body 10. After the first cooling structure 20 and the second cooling structure are both manufactured, the two heat radiation structure bodies 10 are butted and brazed, so that the two slotted structures 11 form the sealed space. Then, the liquid coolant is injected into the sealed space, and the liquid coolant is left for a period of time after injection to cause the liquid coolant to penetrate into capillary structures and the heat radiation structure body 10 as much as possible. Then, the remaining part or all of the liquid coolant is extracted through an injection hole formed in the heat radiation structure body 10, and the sealed space is evacuated. After evacuation, the injection hole is closed.

When the implementation of one heat radiation structure body 10 is selected, Al powder or Cu powder is first sintered on a side wall and a bottom wall of the slotted structure 11 to form the first cooling structure 20, then a sealing cover covers a body of the slotted structure 11, the sealing cover is welded to the slotted structure 11 by brazing to form the sealed space, and the liquid coolant is injected into the sealed space through the injection hole of the sealing cover to cause the liquid coolant to enter cooling channels of the first cooling structure 20, then part of the liquid coolant in the sealed space is extracted, and finally the injection hole is sealed.

In the above implementation that one heat radiation structure body 10 is sealed by the sealing plate 30 to form the sealed space, and after the liquid coolant is injected, the sealed space is evacuated at a predetermined time interval.

The embodiments of the present disclosure further provide a computer, which includes a CPU, a fan, and a heat sink. The fan and the heat sink are respectively arranged on two opposite sides of the CPU, or the CPU and the fan are respectively arranged on two opposite sides of the heat sink, and the heat sink is the above heat sink, or the heat sink is manufactured by the above heat sink manufacturing method.

In the computer of the present disclosure, two heat sinks may be arranged according to the requirements for space and heat radiation in a host computer. The two heat sinks may be stacked and fixed together by screws. At this time, the two heat sinks are located on the same side of a heat source. In another embodiment, the two heat sinks may also be symmetrically arranged on two opposite sides of the CPU to dissipate heat at the two opposite ends of the CPU at the same time.

In an embodiment, the computer may further include more than three heat sinks. A plurality of heat sinks are arranged around the heat source at intervals, or a mixed manner of the above two implementations.

The heat sink in the embodiments of the present disclosure may cope with the heat radiation of a high-power CPU through the above arrangement and manufacturing, thereby achieving a better heat radiation effect.

It is to be noted that terms used herein are only for the purpose of describing the specific implementations and not intended to limit exemplary implementations of the present disclosure. For example, singular forms, used herein, are also intended to include plural forms, unless otherwise clearly pointed out. In addition, it is also to be understood that terms “contain” and/or “include” used in the specification refer/refers to existence of features, steps, operations, apparatuses, components and/or combinations thereof.

Unless otherwise specified, relative arrangements of components and steps elaborated in these embodiments, numeric expressions and numeric values do not limit the scope of the present disclosure. Furthermore, it is to be understood that for ease of descriptions, the size of each part shown in the drawings is not drawn in accordance with an actual proportional relation. Technologies, methods and devices known by those of ordinary skill in the art may not be discussed in detail. However, where appropriate, the technologies, the methods and the devices shall be regarded as part of the authorized description. In all examples shown and discussed herein, any specific value should be interpreted as only exemplar values instead of limited values. As a result, other examples of the exemplary embodiments may have different values. It is to be noted that similar marks and letters represent similar items in the following drawings. As a result, once a certain item is defined in one drawing, it is unnecessary to further discus the certain item in the subsequent drawings.

In the description of the present disclosure, it is to be understood that the orientations or positional relationships indicated by the orientation words “front, rear, upper, down, left and right”, “transverse, longitudinal, vertical and horizontal”, “top and bottom”, etc. are based on the orientations or positional relationships shown in the drawings, and are only for the convenience of describing the present disclosure and simplifying the description. Unless stated to the contrary, these orientation words do not indicate or imply that the apparatus or element referred to must have a specific orientation, be constructed and operated in a specific orientation, and therefore cannot be construed as limiting the scope of protection of the present disclosure. The orientation words “inside and outside” refer to inside and outside relative to the outline of each part itself.

For ease of description, spatially relative terms such as “over”, “above”, “on an upper surface” and “upper” may be used herein for describing a spatial position relation between a device or feature and other devices or features shown in the drawings. It should be understood that the spatially relative terms are intended to contain different orientations of the device in usage or operation besides the orientations of the devices described in the drawings. For example, if the devices in the drawings are inverted, those described as “above other devices or structures” or “over other devices or structures” will then be positioned as “below other devices or structures” or “under other devices or structures”. Thus, the exemplary term “above” may include both “above” and “below” orientations. The device may also be positioned in various other ways (rotated 90 degrees or at other orientations) and the spatially relative descriptions used herein are interpreted accordingly.

Furthermore, it is to be noted that the use of the words “first”, “second” and the like to define parts is only for the convenience of distinguishing the corresponding parts, unless otherwise stated, the words have no special meaning, and therefore cannot be construed as limiting the scope of protection of the present disclosure.

The above are only the preferred embodiments of the present disclosure, and is not intended to limit the present disclosure, and for those of ordinary skill in the art, various modifications and changes can be made to the present disclosure. Any modifications, equivalent substitutions, improvements, etc. within the scope of the present disclosure shall be included in the principle of the present disclosure.

1. A heat sink, comprising:
a heat radiation structure body, the heat radiation structure body is configured to arrange on one side of a heat source, the heat radiation structure body is provided with a slotted structure, the slotted structure extends in a direction away from the heat source, wherein an opening of the slotted structure is formed in one end of the heat radiation structure body away from the heat source; and
a first cooling structure, the first cooling structure is laid on an inner wall of the slotted structure, wherein the first cooling structure is provided with first cooling channels for adsorbing a liquid coolant.

2. The heat sink according to claim 1, wherein the first cooling structure is a capillary structure, and pores in the capillary structure form the first cooling channels

3. The heat sink according to claim 2, wherein a cross-section of the slotted structure is circular or rectangular, wherein the first cooling structure is arranged on a side wall and a bottom wall of the slotted structure.

4. The heat sink according to claim 1, wherein the heat radiation structure body is made from a vapor chamber.

5. The heat sink according to claim 4, wherein a ratio of a thickness of the bottom wall of the slotted structure to a thickness of the vapor chamber is 0.05 to 0.1.

6. The heat sink according to claim 5, wherein the thickness of the bottom wall of the slotted structure is 2 mm to 3 mm, and the thickness of the vapor chamber is 30 mm to 35 mm.

7. The heat sink according to claim 1, wherein the heat radiation structure body is of a radial structure, and the slotted structure is arranged at a center of the heat radiation structure body.

8. The heat sink according to claim 1, wherein the first cooling structure is made of Al powder or Cu powder, wherein the Al powder or the Cu powder is 200 mesh to 800 mesh.

9. The heat sink according to claim 1, wherein two heat radiation structure bodies are provided, the two heat radiation structure bodies are arranged in a mirror image manner, wherein openings in the two heat radiation structure bodies are arranged opposite to each other, so that slotted structures on the two heat radiation structure bodies jointly enclose a sealed space.

10. The heat sink according to claim 9, wherein the first cooling structure is arranged in the heat radiation structure body at one end close to the heat source, and the heat sink further comprises:
a second cooling structure, the second cooling structure is configured to arrange in the heat radiation structure body at one end away from the heat source, wherein the second cooling structure further comprises a plurality of second cooling channels, the liquid coolant is pre-stored in the plurality of second cooling channels, and the second cooling structure is only laid on the side wall of the slotted structure.

11. The heat sink according to claim 1, further comprising:
a sealing plate, the sealing plate is arranged at the opening of the slotted structure to cooperate with the slotted structure-to form a sealed space.

12. The heat sink according to claim 11, wherein the opening of the slotted structure is provided with a counter bore, a depth of the a counter bore is less than or equal to a thickness of the sealing plate, and the sealing plate completely falls into the counter bore.

13. The heat sink according to claim 11, wherein the sealed plate is provided with a groove on one side of the sealed space.

14. The heat sink according to claim 13, wherein the groove is of a groove structure with a deep middle and a shallow edge.

15. A heat sink manufacturing method, comprising:
machining a slotted structure on an end surface of one end of a heat radiation structure body away from a heat source; and
laying a first cooling structure on an inner wall of the slotted structure, causing the first cooling structure to comprise first cooling channels, and pre-storing a liquid coolant in the first cooling channels.

16. The heat sink manufacturing method according to claim 15, wherein the first cooling structure is formed by sintering Cu powder or Al powder on the inner wall of the slotted structure.

17. The heat sink manufacturing method according to claim 15, wherein two heat radiation structure bodies are placed together in a mirror image manner with one end away from the heat source as the center and are welded and fixed, so that slotted structures on the two heat radiation structure bodies form a sealed space.

18. The heat sink manufacturing method according to claim 15, wherein a sealing plate covers an opening of the slotted structure and is welded and sealed, so that a sealed space is formed between the slotted structure and the sealing plate.

19. The heat sink manufacturing method according to claim 17, wherein,
after the first cooling structure is laid, the liquid coolant is injected into the slotted structure to cause the liquid coolant to flow into the first cooling channels; and
after the liquid coolant is injected, the sealed space is evacuated at a predetermined time interval.

20. A computer, comprising a Central Processing Unit (CPU) and a heat sink, wherein the heat sink is arranged on one side of the CPU, and the heat sink is the heat sink according to claim 1, or the heat sink is manufactured by the heat sink manufacturing method according to claim 15.
